(19) United States
(12) Patent Application Publication
(10) Pub. No.: US 2019/0034105 A1
(43) Pub. Date: Jan. 31, 2019

(54) STORAGE DEVICE HAVING PROGRAMMED CELL STORAGE DENSITY MODES THAT ARE A FUNCTION OF STORAGE DEVICE CAPACITY UTILIZATION

(71) Applicant: Intel Corporation, Santa Clara, CA (US)

(72) Inventors: Shankar NATARAJAN, Folsom, CA (US); Ramkarthik GANESAN, Folsom, CA (US)

(21) Appl. No.: 15/857,530

(22) Filed: Dec. 28, 2017

(51) Int. Cl. G06F 3/06; G11C 11/56

(52) U.S. Cl. CPC G06F 3/0634; G11C 11/56; G06F 3/0688; G06F 3/0604

(57) ABSTRACT

A method is described. The method includes programming multi-bit storage cells of multiple FLASH memory chips in a lower density storage mode. The method also includes programming the multi-bit storage cells of the multiple FLASH memory chips in a higher density storage mode after at least 25% of the storage capacity of the multiple FLASH memory chips has been programmed.

### FIELD OF INVENTION

The field of invention pertains generally to a storage device having programmed cell storage density modes that are a function of storage device capacity utilization.

### BACKGROUND

As computing systems become more and more powerful their storage needs to continue to grow. In response to this trend, mass storage semiconductor chip manufacturers are developing ways to store more than one bit in a storage cell. Unfortunately, such cells may demonstrate slower programming times as compared to their binary storage cell predecessors. As such, mass storage device manufacturers are developing new techniques for speeding-up the performance of storage devices composed of memory chips having higher density but slower cells.

### FIGURES

A better understanding of the present invention can be obtained from the following detailed description in conjunction with the following drawings, in which:

FIGS. 1a, 1b, 1c, 1d, 1e, 1f and 1g depict a pattern for programming multi-bit FLASH storage cells as a function of SSD storage capacity utilization;

FIG. 2 shows charge transfer from MLC mode to QLC mode;

FIG. 3 shows an SSD capable of implementing the write pattern of FIGS. 1a through 1g;

FIG. 4 shows a method performed by the SSD of FIG. 3;

FIG. 5 shows a computing system.

### DETAILED DESCRIPTION

The construction of a FLASH memory device may be seen as a three-dimensional arrangement of storage cells composed of an array of columns that extend vertically above the semiconductor substrate, where, each column includes a number of discrete storage cells that are stacked upon one another. A storage block corresponds to a number of such columns. In order to access certain ones of the storage cells within a storage cell block, word-line wire structures (“word lines”) are coupled to same vertically positioned storage cells within different columns of the storage cell block.

For example, if a storage block's columns are each composed of a vertical stack of eight storage cells, eight different word lines may be used to access respective cells at the eight different storage levels of the storage block's columns (e.g., a first word line may be coupled to the lowest cell in each of the columns, a second word line may be coupled the second lowest cell in each of the columns, etc.). In the case of FLASH memories whose storage cells can each store more than one bit, multiple pages of information may be accessed through a single word line. Here, a mass storage device is traditionally accessed (read/write) in blocks of data where each block is composed of multiple pages. A FLASH memory device that can store more than one bit per storage cell is typically capable of accessing different pages by activating a single word line within a storage block where the pages are stored.

A storage block is generally the smallest unit at which storage cells can be erased (cells of a same block are erased together) and a page is generally the smallest unit at cells can be written or “programmed”. Thus, for instance, if a host commands an SSD to write a number of pages, multiple ones of the pages may be programmed within a same storage block by activating a single word line. The number of word lines that are activated in order to fully execute the write command depends on how many pages are associated with the write and how many pages are accessible per word line. A single FLASH memory chip is also typically composed of multiple planes where each plane includes its own unique set of storage blocks within the chip.

As alluded to above, different FLASH memory technologies are generally characterized by how many bits can be stored per storage cell. Specifically, a single level cell (SLC) stores one bit per cell, a multiple level cell (MLC) stores two bits per cell, a ternary level cell (TLC) stores three bits per cell and quad level cell (QLC) stores four bits per cell. Whereas an SLC cell is only capable of storing two logic states per cell (a “1” or a “0”), each of the MLC, TLC and QLC cell types, which may be characterized as different types of “multi-bit” storage cells, greatly expand the storage capacity of a FLASH device because more than two digital states can be stored in a single cell (e.g., four digital states can be stored in an MLC cell, eight digital states can be stored in a TLC cell and sixteen logic states can be stored in a QLC cell).

A tradeoff exists, however, with respect to storage density per cell and access time per cell. That is, generally, the more bits that a storage cell stores, the longer the amount of time is needed to write information to the cell. Here, a storage cell that stores more bits can be seen as having tighter charge storage tolerances than storage cells that store fewer bits. That is, a cell that stores more bits has smaller amounts of charge differentiating between the different logical states it can store, whereas, a cell that stores fewer bits has greater amounts of charge differentiating between the logical states that is can store.

A FLASH cell is programmed or erased by pumping it with charge. Cells that store fewer bits per call, having a greater difference between their stored charge states than cells that store more bits per cell, use a more “coarse-grained” pumping process that applies larger charge increments in fewer pump cycles than cells that store more bits per cell which use a more “fine-grained” pumping process that applies smaller charge increments over more pump cycles (at least for its largest pumped charge amounts). The fewer pump cycles associated with cells that store less bits results in such cells exhibiting reduced program access times, on average, as compared to cells that store more bits.

Thus, although next generation FLASH manufacturing technologies are providing increased performance in terms of storage capacity per cell, at the same time, performance is decreased in terms of average program time per cell.

In order to address the trade-off, FLASH based storage devices, such as solid state drives (SSDs), are implementing storage buffers composed of cells that store fewer bits per cell than what their underlying manufactured technology is capable of storing. For example, an SSD composed of QLC FLASH memory chips will use some percentage of its QLC cells to operate in an SLC or MLC mode. The cells that operate in the lower density mode are used by the SSD as a cache-like buffer into which newly incoming data is written. By writing new incoming data into the buffer composed of reduced density but faster cells, the raw program access times of the SSD are observed as being faster.

Complications, however, exist with respect to the implementation of such buffers. A first complication is that the buffer has to be constantly “cleared” of its content by writing its content back into the higher density cells as a background process. Here, generally, an SSD buffer represents only 1 or 2 percent over the overall storage capacity of the SSD. If the contents of the buffer are not regularly written back to the higher density cells, the buffer will fill-up and not be available for a next write to the SSD. Unfortunately, the background process itself can block the buffer for a new write command (if the buffer is being cleared when a new write command arrives, the write command must wait until the buffer is cleared or the background process can be suspended). Additionally, the background process increases the overall complexity of the SSD's operation which results in, e.g., increased power consumption, cost and/or failure mechanisms.

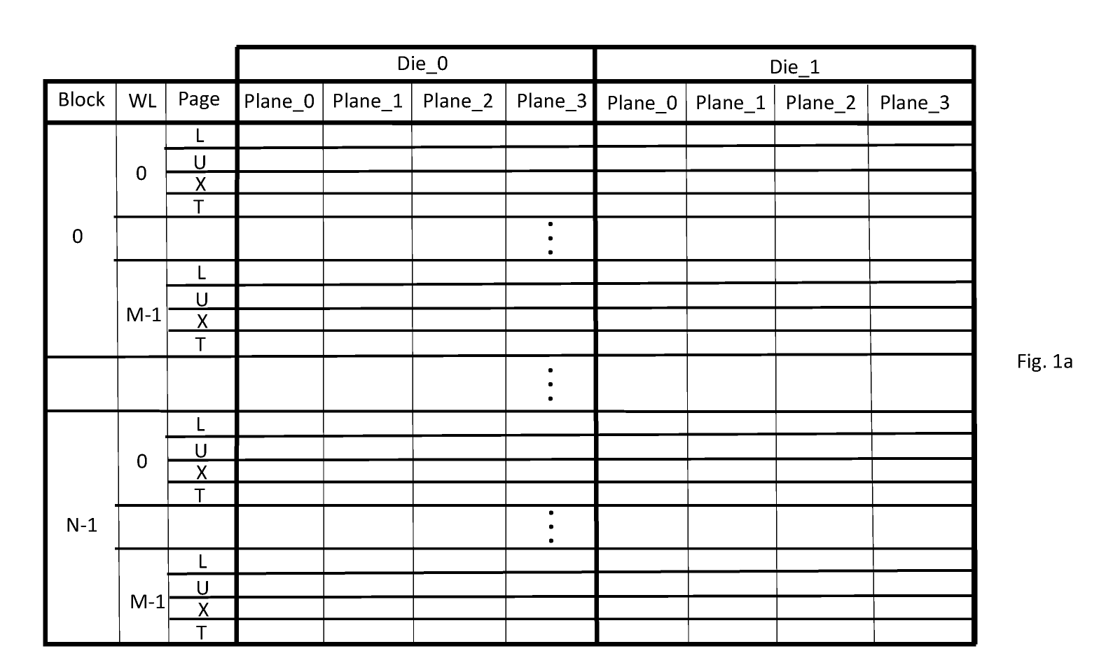

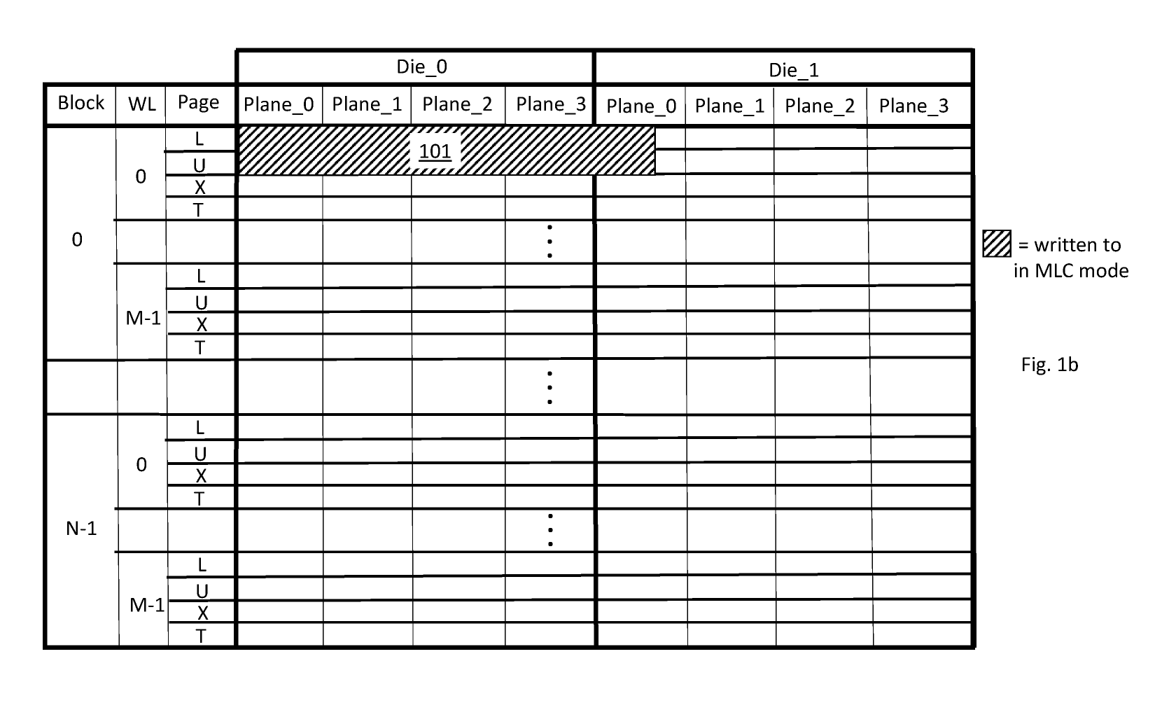

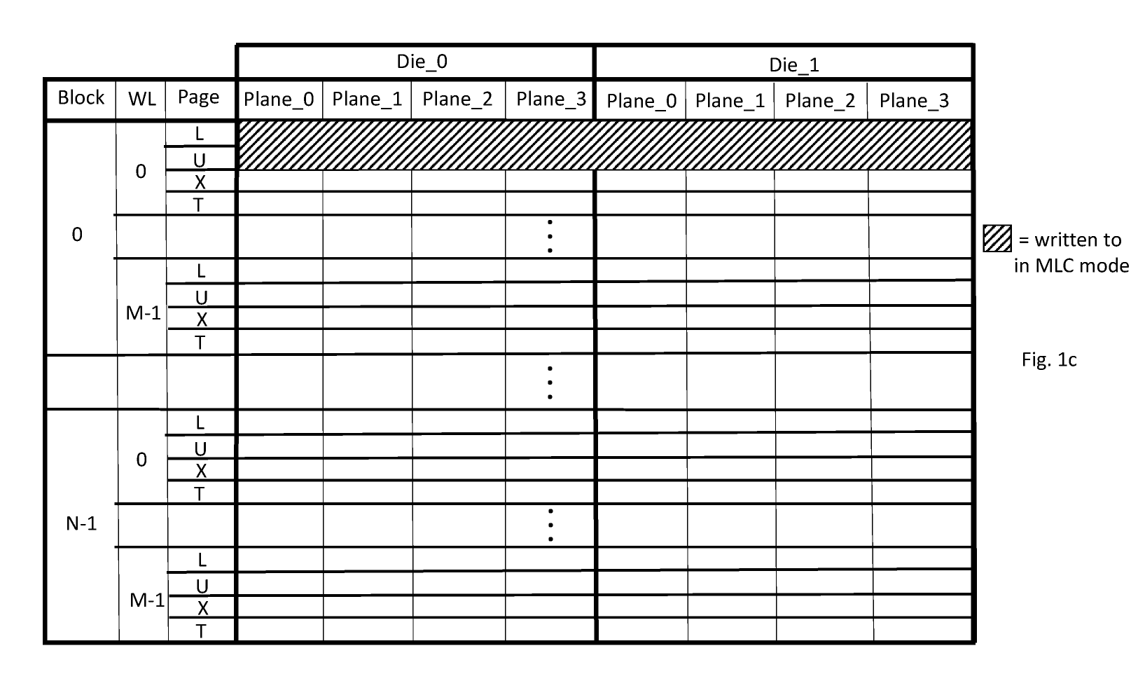

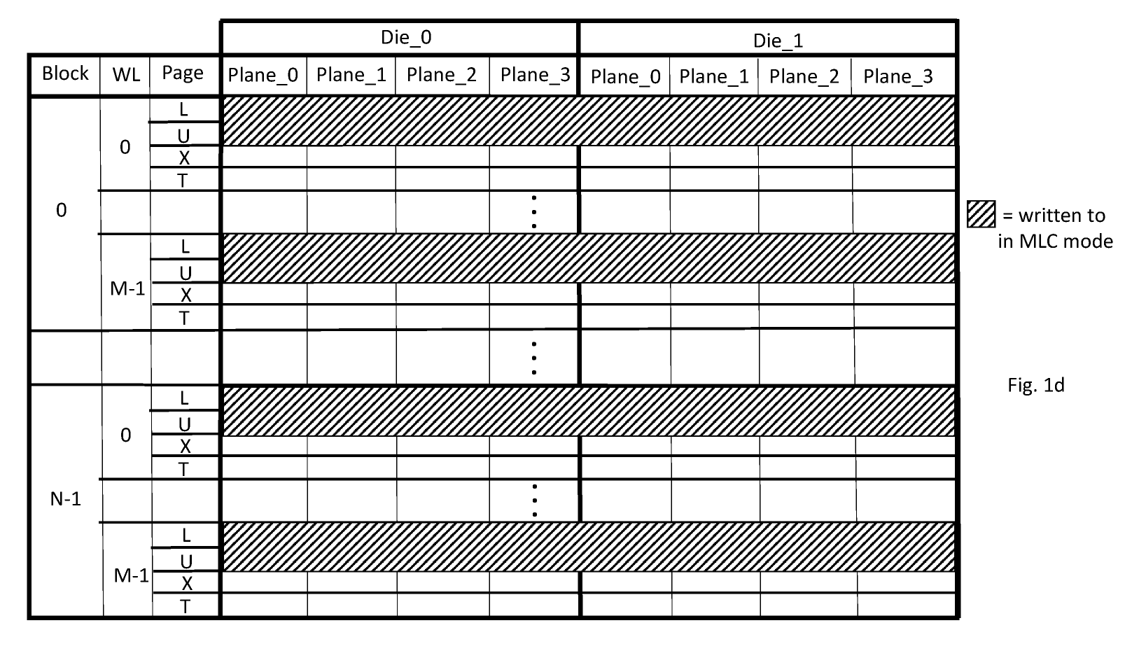

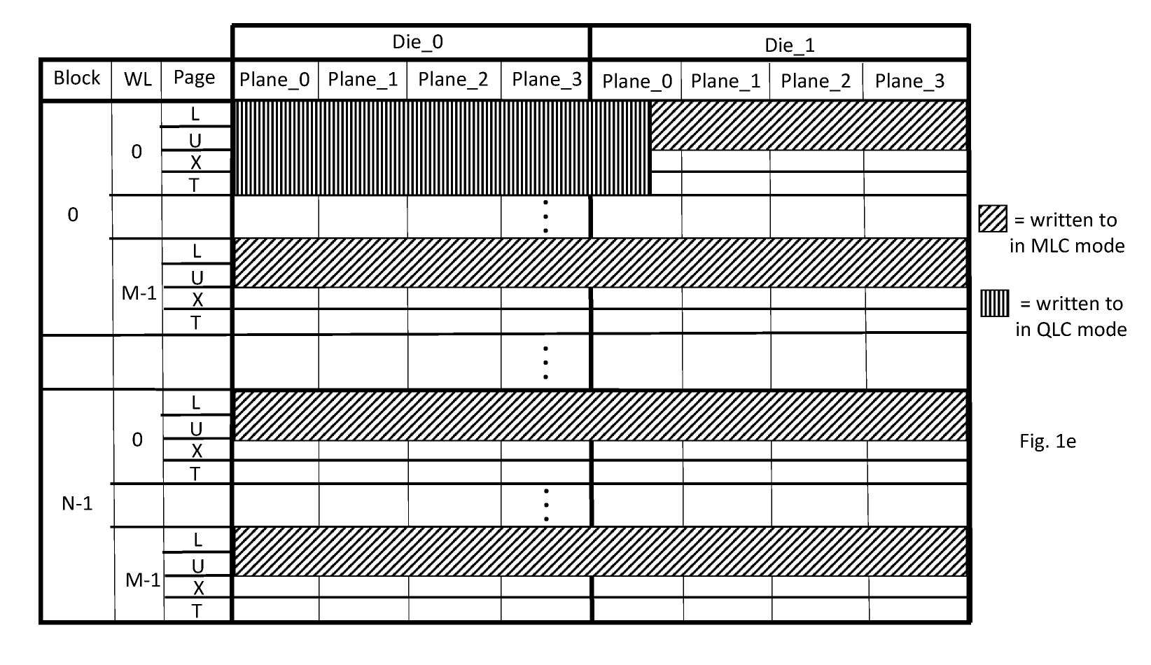

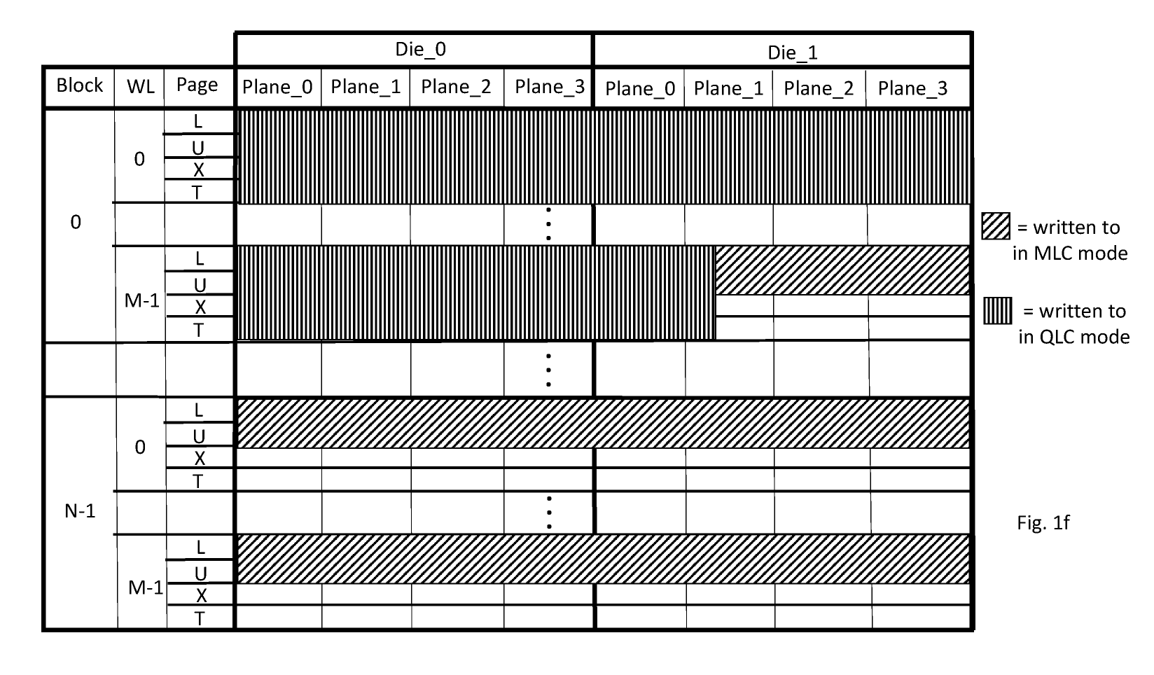

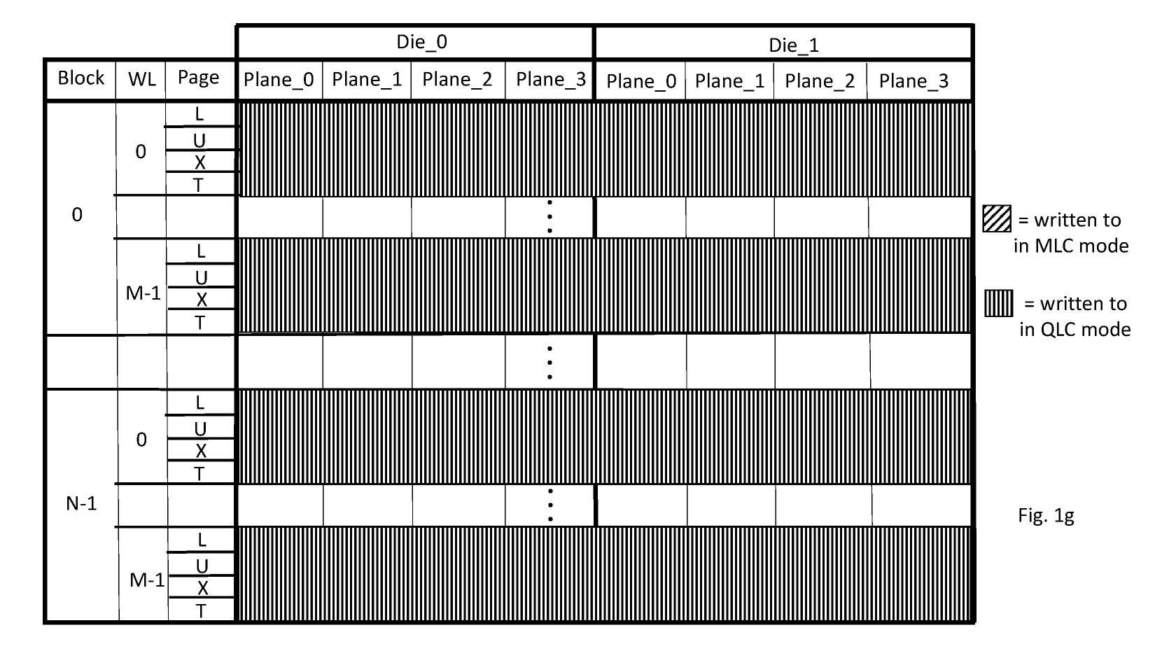

FIGS. 1a through 1f depict the operation of an improved SSD design that uses a much larger percentage of the device's higher density storage cells in a lower density mode. Additionally, these cells operate more as standard storage cells of the device and less as a buffer for the device as described above. As a consequence, the problems described just above with respect to the continued execution of a high maintenance background process should be diminished.

As depicted in FIG. 1a, the SSD can be viewed as being composed of multiple FLASH memory chips each composed of N storage blocks. For simplicity the exemplary architecture of FIG. 1a assumes the presence of only two FLASH memory chips within the SSD (Die_0 and Die_1). Those of ordinary skill, however, will be able to readily apply the teachings of the exemplary device described herein to other devices that include more than two FLASH memory chips. Both of the memory devices are composed of four planes (Plane_0 through Plane_3), where, each plane includes N storage blocks (thus, there are 4×N storage blocks per memory device). Each storage block includes M word lines and each word line supports access to four different pages (lower (L), upper (U), Xtra (X) and Top (T)) when operating in its highest density QLC mode. FIG. 1a shows, e.g., an initial state when the device is first used and has not yet stored any random customer data.

FIG. 1b shows the state of the SSD after a first number of pages 101 have been programmed into the device. Here, an SSD includes a controller that manages a mapping table (also referred to as an address translation table) that maps logical addresses to physical addresses. When a host sends a block of data to be written into the SSD, the host also appends a block address to the data which is referred to as a logical block address (LBU). The SDD then writes the block of data into the SSD and associates, within the mapping table, the data's LBU to the physical location(s) within the SSD where the block's pages of data are stored. The specific physical locations are specified with a physical block address (PBA) that uniquely identifies the one or more die, plane, block, word line and page resources within the SSD where the pages are stored.

As can be seen in FIG. 1b, the exemplary SSD sequentially programs incoming pages to same storage block and word line (WL) locations across different planes and different memory chips so that the consumed storage amount is observed to expand horizontally from left to right across a same block and word line location in FIG. 1b. Different SSD implementations may employ different write patterns. For instance, in another approach, the SSD may write incoming pages sequentially across same die and plane resources across different blocks and word lines (in which case, consumed storage capacity would be observed to expand vertically from top to bottom along a same plane within a same die).

As can be seen in FIG. 1b, the programming of these initial pages includes writing to cells that are operating in a lower per cell storage capacity (MLC) than what the underlying manufacturing technology supports as its maximum density (QLC). The writing of the pages to cells in the lower density MLC mode improves the program access time performance of the SSD as compared to an approach in which the pages are only written to cells in the maximum density QLC mode. That is, as described above, lower storage capacity cells have lower write access times than higher density cells.

Additionally, because of the reduced storage density, only half of the page capacity per word line is consumed. That is, e.g., with the cells operating in an MLC mode in which only two bits are stored per cell, only two pages can be stored per word line. As will be explained in more detail further below, the unused half of the page storage capacity may be consumed if a threshold amount of the SSD's overall storage cell capacity is consumed which, in turn, may justify the switching over of these cells from lower density MLC mode to higher density QLC mode.

The pattern of writing to only half a word line's potential page storage is directly observable from FIG. 1b in that only two pages (L and U) of block address 0 (BA=0) and word line address 0 (WL=0) are written across multiple planes and die. Here, with 50% of the potential capacity of the storage blocks being unused during the initial programming 101 of pages to the SSD, two blocks are needed to write four pages of information (even though four pages of information can be stored at a single word line of a single block in QLC mode). That is, since the cells are operating in the lower density mode (two bits per cell mode) each block is only capable of storing two pages per word line. As such, a second block and word line combination is needed to store third and fourth pages, whereas, if the cells were operating in the higher density mode (four bits per cell mode), four pages could be programmed per block and word line combination.

Again, in an alternate implementation that uses a write pattern in which data is written sequentially across different blocks and word lines of same plane and die, after pages L and U are written to at BA=0 and WL=0 of plane 0 of die 1, the SSD may, e.g., write pages L and U at BA=0 and WL=1 of plane 0 of die 1. In this particular embodiment, again, only half the storage potential storage capacity along a particular word line is programmed. Thus, there exist a myriad of different storage block and word line combination sequences that can be used to define a particular programming pattern as new pages are being written into the SSD. For ease of discussion, the remainder of the instant description will largely refer only to an embodiment in which the page write patterns are as depicted in FIGS. 1b through 1f.

FIG. 1c shows a further state of the SSD after additional new pages have been programmed into the SSD in low density mode. Here, as can seen in FIG. 1c, all L and U page locations at BA=0 and WL=0 have been written to at the lower per cell storage density across all planes of both dies within the SSD. Thus, with all cells at locations BA=0 and WL=0 across the SSD having been written to in low density mode such cells are at their present mode's maximum capacity (two pages per word line) but not their potential maximum capacity (four pages per word line). That is, as can be seen from FIG. 1c, page locations X and T have not been written to across these same storage blocks, planes and dies resulting in 50% under-utilization of the potential maximum storage capacity of these blocks. However, the programming of these pages was able to transpire in less time because of the operation of the storage cells in the reduced density storage mode.

FIG. 1d shows another further state of the SSD after an additional number of pages whose combined data amount corresponds to 50% capacity of the SSD's maximum capacity have been programmed into the SSD according to the aforementioned write pattern. Here, again, the cells that have been written to are operating in a lower density mode which has improved the write access times of the SSD up to 50% utilization of the SSD's storage capacity. Recalling the discussion at the onset of the present description that traditional SSD buffers typically only use 1% or 2% of the SSD's storage cells, note that the improved approach described herein should demonstrate SSD performance “as if” the SSD was composed of a buffer that consumed 50% of the SSD's storage cells.

Importantly, with such a large effective buffer, there is little/no need to implement a costly and high maintenance background process that is constantly reading information out of the buffer to create available space on account of the buffer's small size. Rather, the effective buffer of the improved approach has an initial capacity that is 50% of the storage capacity of the SSD. With such a large effective buffer, at least initially, data does not need to be continuously read out of the effective buffer, rather, the programmed data can simply remain in place according to a standard cell storage usage model.

FIGS. 1e through 1f show the write pattern continuing onward from the state of FIG. 1d after the SSD programs even more pages into the SSD. Here, after the state of FIG. 1d in which 50% of the storage capacity of the SSD is consumed but 100% of the storage cells are in use at 50% of their maximum storage capacity, cells will need to be switched over from an MLC mode to their full QLC mode in order to accommodate the storage of more pages.

As such, as observed in FIG. 1e, the write pattern repeats for a second pass, but in QLC density mode rather than MLC density mode. As such, storage capacity for two more pages are available along all BA=0 and WL=0 locations across the different planes and dies of the SSD. Specifically, FIG. 1e depicts the heretofore unused capacity of these locations being consumed with data at page locations X and T of the BA=0 and WL=0 locations across the different planes and die of the SSD. The writing of the pages in the maximum cell density mode, may slow down the performance of the SSD as compared to the first 50% cell utilization because of the longer write times associated with QLC mode. Said another way, the SSD will exhibit MLC-like speeds up to the first 50% capacity utilization of the SSD. After the first 50% of the SSD's storage capacity is utilized (FIG. 1d into FIG. 1e), the SSD's performance will experience some diminishment owing to the introduction of the slower QLC programming process.

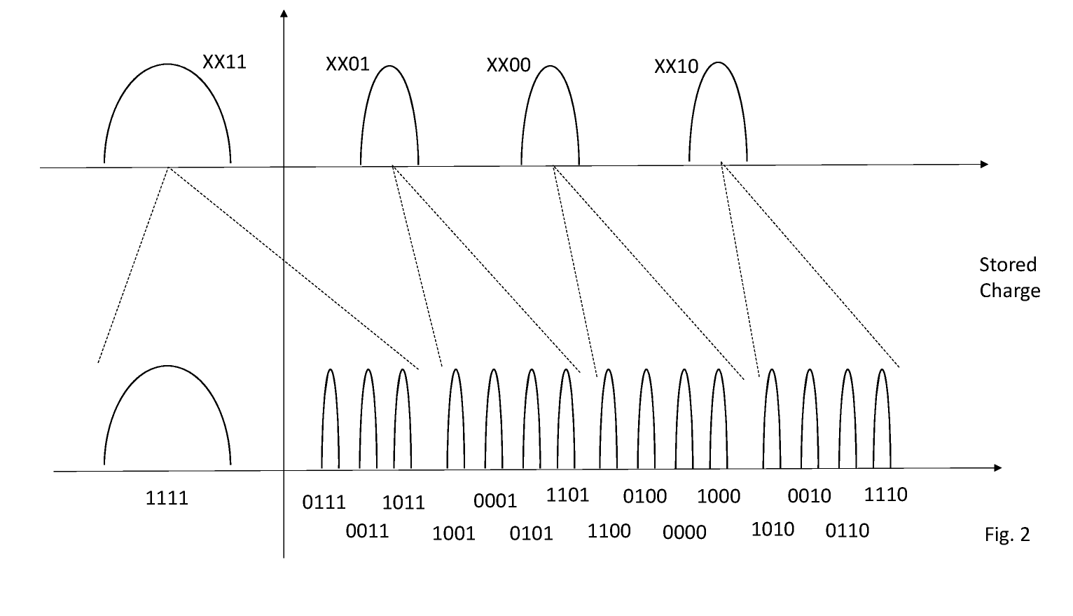

According to one approach, in order to program over cells storing MLC data with QLC data, the charge distributions in the original MLC mode are converted to QLC mode according to the charge distribution transfer diagram provided in FIG. 2. Here, as can be seen, the two bits that were stored per cell are converted into the two lowest ordered bits in the four bit QLC mode. Comparing FIG. 2 with FIGS. 1a through 1f, the L and U pages occupy the lowest ordered bits of the four stored bits in the new QLC mode whereas the X and T pages of the newly written pages occupy the two highest ordered bits of the stored four bits in QLC mode. In an embodiment, the four stored bits per cell are organized, in terms of the pages they represent, as T, X, U, L from the highest ordered bit to the lowest ordered bit.

In various embodiments, in order to properly perform the MLC to QLC charge redistributions when writing the second pass of the write pattern at QLC densities, a pair of bits that was originally stored in a cell during the first pass in MLC mode is read from the cell and then combined with the new data to be written into the cell. The four combined bits (two original and two new) are then programmed into the cell.

FIGS. 1f and 1g show following states that are comparable in terms of numbers of additional stored pages with FIGS. 1c and 1d, respectively. As can be seen in FIGS. 1f and 1g, the cells in the SSD are continually overwritten during the second pass in the maximum per cell storage density mode which expands each cell's capacity to store two additional bits from each of two additional pages X and T. Thus, as of the state of the SSD of FIG. 1g, the full storage capacity of the SSD has been reached.

In various embodiments, information maintained by the wear leveling function of the SSD may be used to minimize any observed performance hit to the SSD as a consequence of the switching over to the higher density, slower cells. Here, as is known in the art, storage cells that are written to more frequently will wear-out faster than cells that are written to less frequently.

The SSD's controller therefore performs wear leveling to remap “hot” blocks of information that are frequently accessed to “colder” blocks that have only been infrequently accessed. Here, the controller monitors the access rates (and/or total accesses) for the SSD's physical addresses and maintains an internal map that maps these physical addresses to the original LBUs provided by the host. Based on the monitored rates and/or counts, the controller determines when certain blocks are deemed to be “hot” and need to have their associated data swapped out, and, determines when certain blocks are deemed to be “cold” and can receive hot blocks of data. In traditional wear-leveling approaches, the information in the colder blocks may also be swapped into the hot blocks.

In order to reduce the impact of the programming performance drop that will be observed once the higher density cell storage mode begins to be utilized, the hot and cold block data that is maintained by the wear leveling function may also be used to keep hot pages in the cells that are operating in MLC mode and keep cold pages in storage cells that are operating in the QLC mode. Here, for instance, FIG. 1e shows an SSD where a substantial percentage of the SSD's storage cells are operating in MLC mode and a substantial percentage of the SSD's storage cells are operating in WLC mode. Thus, there may exist sufficient numbers of hot blocks within in the slower QLC cells and sufficient numbers of cold blocks within the faster MLC cells. The wear leveling data maintained by the controller may be used to intelligently swap the locations of these pages so the hot blocks are moved to the faster MLC cells and the cold blocks are moved to the slower QLC cells.

Note that is capacity utilization falls to 50% or lower the SSD can return to operating entirely in MLC mode.

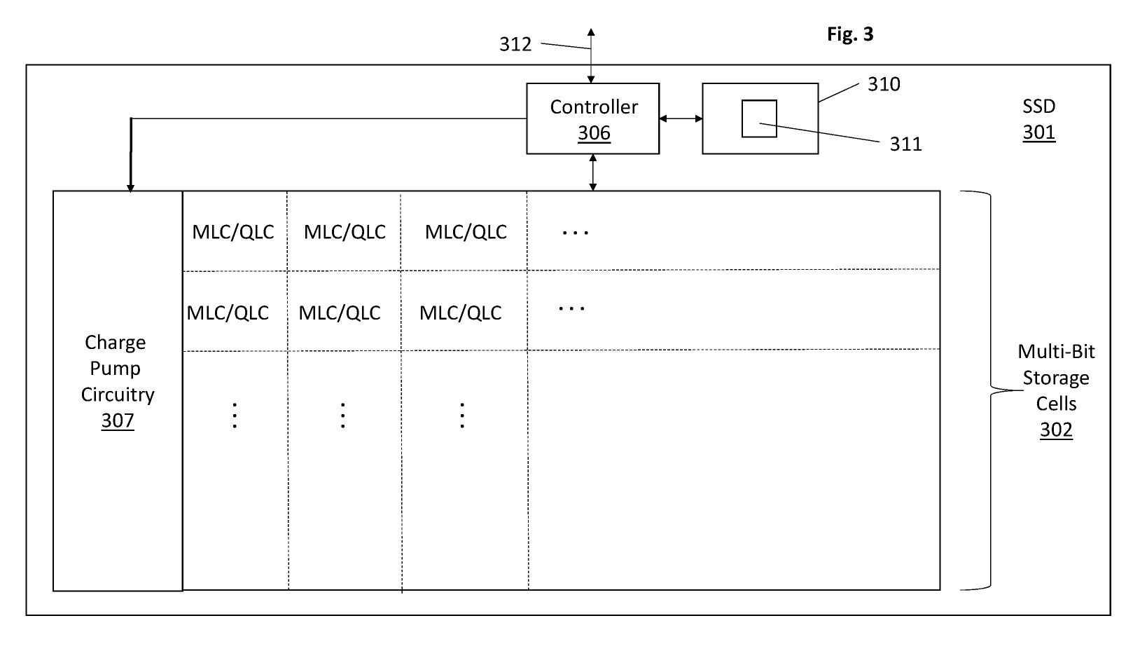

FIG. 3 shows an embodiment of an SSD 301 that can operate consistently with the teachings provided above. As observed in FIG. 3, the SSD includes many storage cells 302 that are capable of storing more than one bit. Additionally, most or all of the SSD's storage cells are operable in both MLC and QLC modes. Which one of these modes any particular one of these cells operates in depends upon the storage capacity utilization of the SSD (e.g., at 50% or less overall capacity utilization all cells operate in MLC mode, between 50% and 100% capacity utilization some cells operate in MLC mode while others operate in QLC mode, at 100% capacity utilization all cells operate in QLC mode).

The SSD includes a controller 306 that is responsible for determining which cells operate in MLC mode and which cells operate in QLC mode. According to one embodiment, described at length above, a first programming pass is applied to all cells in MLC mode and then a second pass is applied to all cells in QLC mode. The capacity utilization information and/or information that identifies which cells are operating in which mode 311 is, e.g., maintained in memory and/or register space 310 that is coupled to and/or integrated within the controller 306. In one embodiment, such information is manifested with an MLC/QLC bit or similar digital record for each physical address or whatever granularity (e.g., block ID) at which a set of cells are treated identically as a common group concerning their MLC/QLC mode of operation.

Thus, if such granularity is block level, each block is identified in information 311 and further specifies MLC the first time each of these blocks is programmed. Above 50% capacity utilization, when the SSD begins to convert MLC cells to QLC cells, the information 311 is changed to indicate QLC mode with each MLC block that is newly written over in QLC mode. By the time 100% capacity utilization is reached the information 311 for all of the blocks should indicate QLC mode. The information 311 may also specify which blocks are actually written to so that the controller 306 can determine capacity utilization percentages. Moreover, as described above, the information 311 may be used to enhance the wear-leveling algorithm that is executed by the controller 306. Specifically, the wear-leveling algorithm that is executed by the controller 306 may swap hot blocks from QLC blocks to MLC blocks and may swap cold blocks from MLC blocks to QLC blocks.

The controller 306 is also coupled to charge pump circuitry 307 that is designed to create different charge pump signal sequences for the QLC and MLC modes. Here, the controller 306 informs the charge pump circuitry 307 of which signals to apply (MLC or QLC) for any particular programming sequence in conformance with the controller's determination of which mode of operation is appropriate for the cells being written to based on SSD capacity utilization.

The controller may be implemented as dedicated hardwired logic circuitry (e.g., hardwired application specific integrated circuit (ASIC) state machine(s) and supporting circuitry), programmable logic circuitry (e.g., field programmable gate array (FPGA), programmable logic device (PLD)), logic circuitry that is designed to execute program code (e.g., embedded processor, embedded controller, etc.) or any combination of these. In embodiments where at least some portion of the controller 306 is designed to execute program code, the program code is stored in local memory (e.g., a same memory where information 311 is kept) and executed by the controller therefrom. An I/O interface 312 is coupled to the controller 306 and may be compatible with an industry standard peripheral or storage interface (e.g., Peripheral Component Interconnect (PCIe), ATA/IDE (Advanced Technology Attachment/Integrated Drive Electronics), Universal Serial Bus (USB), IEEE 1394 (“Firewire”), etc.)

It is pertinent to recognize that other embodiments may make use of the teachings provided herein even though they depart somewhat from the specific embodiments described above. In particular, other embodiments may alter the percentage SSD capacity utilization at which SSD operation changes new programming from MLC mode to QLC mode. For instance, in one embodiment, cells begin to be written in QLC mode when capacity reaches 25% instead of 50% (or any capacity between 25% and 50%). In this case, e.g., programming in QLC mode commences before the state of FIG. 1d is reached. Various embodiments may also let the user/host configure at which capacity utilization switch-over to QLC mode is to begin. For example, the SSD may support configurable options of 25%, 30%, 33%, 40% and 50%, or, any capacity utilization between 25% and 50% inclusive. Conceivably capacity utilizations less than 25% may also be used to trigger switch-over to QLC mode.

It also pertinent to recognize that a lower density mode of MLC and a higher density mode of QLC is only exemplary and other embodiments may have different lower density modes and/or different higher density modes. For instance, in one embodiment, the lower density is TLC and the higher density is QLC. In this embodiment, note that switchover to the higher density mode may occur when capacity utilization reaches, e.g., 75% (when all cells are programmed with three bits per cell) or less. In another embodiment, the lower density is SLC and the higher density is QLC. In this embodiment, note that switchover to the higher density mode may occur when capacity utilization reaches 25% (when all cells programmed with one bit per cell). The former TLC/QLC SSD has a larger but slower effective buffer than the SLC/QLC SSD which has a smaller but faster effective buffer. Thus, exact percentages of when switchover to higher density mode occurs may also be a function of the specific low and high density modes that are utilized.

The teachings herein can also be applied to systems other than the specific SSD described above with respect to FIG. 3. For example, the function of the controller 306 described above may be partially or wholly integrated into a host system.

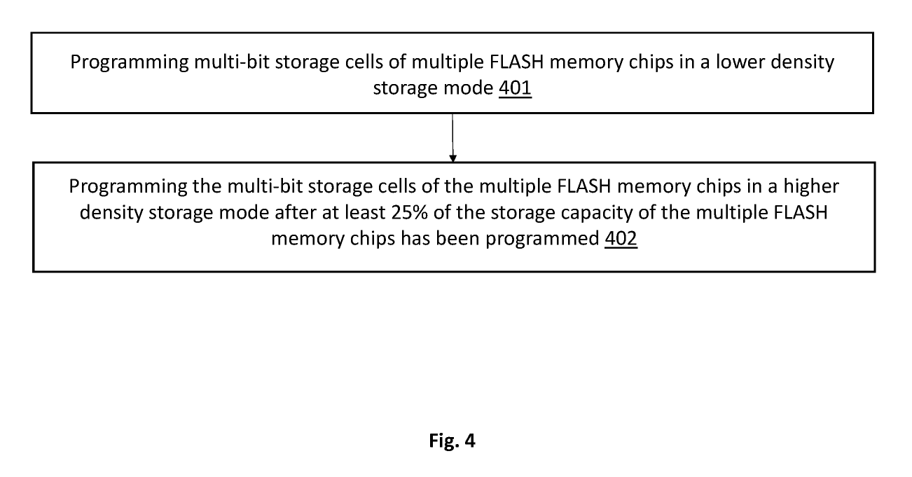

FIG. 4 shows a method that has been described above. The method includes programming multi-bit storage cells of multiple FLASH memory chips in a lower density storage mode 401. The method also includes programming the multi-bit storage cells of the multiple FLASH memory chips in a higher density storage mode after at least 25% of the storage capacity of the multiple FLASH memory chips has been programmed 402.

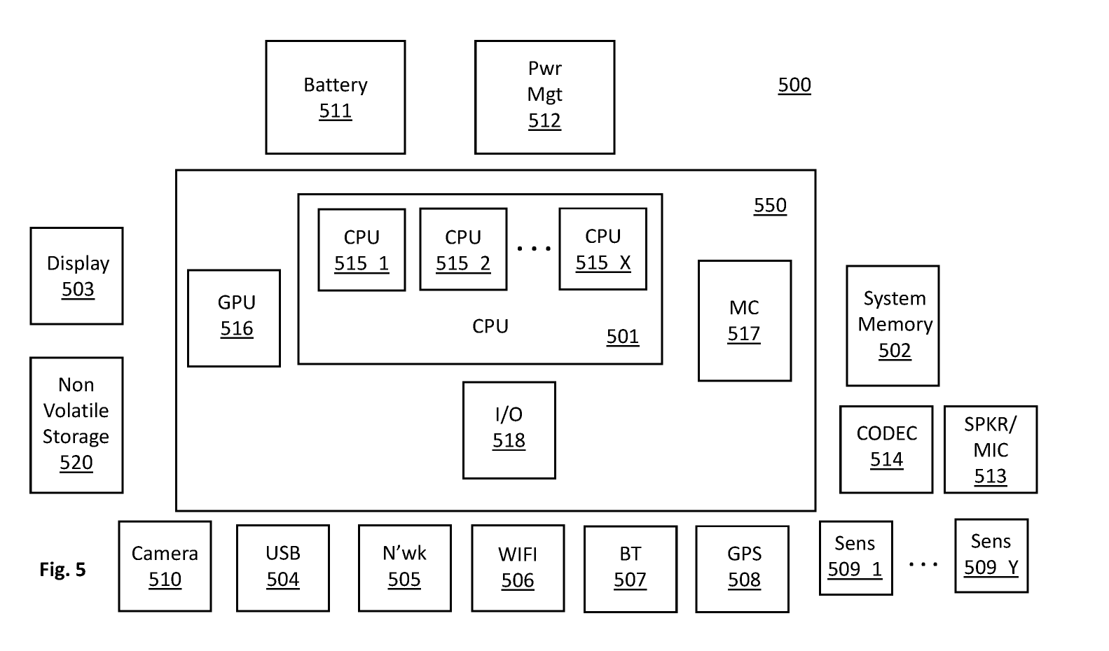

FIG. 5 provides an exemplary depiction of a computing system 500 (e.g., a smartphone, a tablet computer, a laptop computer, a desktop computer, a server computer, etc.). As observed in FIG. 5, the basic computing system 500 may include a central processing unit 501 (which may include, e.g., a plurality of general purpose processing cores 515_1 through 515_X) and a main memory controller 517 disposed on a multi-core processor or applications processor, system memory 502, a display 503 (e.g., touchscreen, flat-panel), a local wired point-to-point link (e.g., USB) interface 504, various network I/O functions 505 (such as an Ethernet interface and/or cellular modem subsystem), a wireless local area network (e.g., WiFi) interface 506, a wireless point-to-point link (e.g., Bluetooth) interface 507 and a Global Positioning System interface 508, various sensors 509_1 through 509_Y, one or more cameras 510, a battery 511, a power management control unit 512, a speaker and microphone 513 and an audio coder/decoder 514.

An applications processor or multi-core processor 550 may include one or more general purpose processing cores 515 within its CPU 501, one or more graphical processing units 516, a memory management function 517 (e.g., a memory controller) and an I/O control function 518. The general purpose processing cores 515 typically execute the operating system and application software of the computing system. The graphics processing unit 516 typically executes graphics intensive functions to, e.g., generate graphics information that is presented on the display 503. The memory control function 517 interfaces with the system memory 502 to write/read data to/from system memory 502. The power management control unit 512 generally controls the power consumption of the system 500.

Each of the touchscreen display 503, the communication interfaces 504-707, the GPS interface 508, the sensors 509, the camera(s) 510, and the speaker/microphone codec 513, 514 all can be viewed as various forms of I/O (input and/or output) relative to the overall computing system including, where appropriate, an integrated peripheral device as well (e.g., the one or more cameras 510). Depending on implementation, various ones of these I/O components may be integrated on the applications processor/multi-core processor 550 or may be located off the die or outside the package of the applications processor/multi-core processor 550.

The computing system also includes non-volatile storage 520 which may be the mass storage component of the system. Here, for example, the mass storage may be composed of one or more SSDs that are composed of FLASH memory chips whose multi-bit storage cells are programmed at different storage densities depending on SSD capacity utilization as described at length above.

Embodiments of the invention may include various processes as set forth above. The processes may be embodied in machine-executable instructions. The instructions can be used to cause a general-purpose or special-purpose processor to perform certain processes. Alternatively, these processes may be performed by specific/custom hardware components that contain hardwired logic circuitry or programmable logic circuitry (e.g., FPGA, PLD) for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed:

1. An apparatus, comprising:
a storage device comprising a controller and a plurality of FLASH memory chips, the plurality of FLASH memory chips comprising three-dimensional stacks of multi-bit storage cells, the multi-bit storage cells having multiple storage density modes, the controller to program the cells in a lower density storage mode up to a storage capacity threshold of the storage device of at least 25%, the controller to program the cells in a higher density mode once the capacity threshold is reached.

2. The apparatus of claim 1 wherein the lower density storage mode is multi-level cell (MLC).

3. The apparatus of claim 2 wherein the higher density storage mode is quad level cell (QLC).

4. The apparatus of claim 3 wherein the storage capacity threshold is 50%.

5. The apparatus of claim 1 wherein the storage capacity threshold is within a range of 25% to 75% inclusive.

6. The apparatus of claim 1 wherein the higher density storage mode is QLC.

7. The apparatus of claim 1 wherein the storage device is a solid state drive.

8. An apparatus, comprising:
a controller to determine programming levels for a plurality of FLASH memory chips, the plurality of FLASH memory chips comprising three-dimensional stacks of multi-bit storage cells, the multi-bit storage cells having multiple storage density modes, the controller to program the cells in a lower density storage mode up to a storage capacity threshold of the FLASH memory chips of at least 25%, the controller to program the cells in a higher density storage mode once the capacity threshold is reached.

9. The apparatus of claim 8 wherein the lower density storage mode is multi-level cell (MLC).

10. The apparatus of claim 9 wherein the higher density storage mode is quad level cell (QLC).

11. The apparatus of claim 10 wherein the storage capacity threshold is 50%.

12. The apparatus of claim 8 wherein the storage capacity threshold is within a range of 25% to 75% inclusive.

13. The apparatus of claim 8 wherein the higher density storage mode is QLC.

14. The apparatus of claim 8 wherein the controller and plurality of FLASH memory chips are components of a solid state drive.

15. A computing system, comprising:
a plurality of processing cores;
a main memory;
a memory controller coupled between the plurality of processing cores and the main memory;
a peripheral hub controller; and,
a solid state drive coupled to the peripheral hub controller, the solid state drive comprising a controller and a plurality of FLASH memory chips, the plurality of FLASH memory chips comprising three-dimensional stacks of multi-bit storage cells, the multi-bit storage cells having multiple storage density modes, the controller to program the cells in a lower density storage mode up to a storage capacity threshold of the storage device of at least 25%, the controller to program the cells in a higher density storage mode once the capacity threshold is reached.

16. The computing system of claim 15 wherein the lower density storage mode is multi-level cell (MLC).

17. The computing system of claim 16 wherein the higher density storage mode is quad level cell (QLC).

18. The computing system of claim 17 wherein the storage capacity threshold is 50%.

19. The computing system of claim 15 wherein the storage capacity threshold is within a range of 25% to 75% inclusive.

20. An article of manufacture comprising stored program code that when processed by a controller of a storage device having multiple FLASH memory chips causes the storage device to perform a method, comprising:
programming multi-bit storage cells of the multiple FLASH memory chips in a lower density storage mode; and,
programming the multi-bit storage cells of the multiple FLASH memory chips in a higher density storage mode after at least 25% of the storage capacity of the multiple FLASH memory chips has been programmed.
